(19) United States
(12) Patent Application Publication
(10) Pub. No.: US 2025/0253302 A1
(43) Pub. Date: Aug. 7, 2025

(54) SEMICONDUCTOR PACKAGE

(71) Applicant: Samsung Electronics Co., Ltd., Suwon-si (KR)

(72) Inventors: Wongil HAN, Suwon-si (KR); Hyosung KOO, Suwon-si (KR); Byongjoo KIM, Suwon-si (KR); Youehwang YOON, Suwon-si (KR); Saetbyeol LEE, Suwon-si (KR)

(73) Assignee: Samsung Electronics Co., Ltd., Suwon-si (KR)

(21) Appl. No.: 18/991,988

(22) Filed: Dec. 23, 2024

(30) Foreign Application Priority Data
Feb. 5, 2024 (KR) 10-2024-0017346

(51) Int. Cl. H01L 25/18; H01L 23/00; H01L 23/31; H01L 23/538; H01L 25/00; H10B 80/00

(52) U.S. Cl. CPC H01L 25/18; H01L 23/3107; H01L 23/5384; H01L 24/48; H01L 25/50; H01L 2224/48147; H01L 2224/48227; H01L 2225/06513; H01L 2225/06541; H01L 2225/06562; H10B 80/00

(57) ABSTRACT

A semiconductor package includes a package substrate including a first conductive pad at an upper portion thereof, a lower semiconductor chip stack structure including dynamic random access memory chips that are stacked in a vertical direction on the package substrate and electrically connected to each other by a through electrode, an upper semiconductor chip stack structure including flash memory chips, each of the flash memory chips may include a second conductive pad at an upper portion thereof, stacked in the vertical direction on the lower semiconductor chip stack structure, a conductive connection pattern contacting an upper surface of the first conductive pad and extending in the vertical direction, and a bonding wire contacting at least one of the second conductive pads and being electrically connected to the conductive connection pattern.

### CROSS-REFERENCE TO RELATED APPLICATION

This application claims priority under 35 U.S.C. § 119 to Korean Patent Application No. 10-2024-0017346, filed on Feb. 5, 2024 in the Korean Intellectual Property Office (KIPO), the contents of which are herein incorporated by reference in their entirety.

### BACKGROUND

### 1. Field

Example embodiments relate to semiconductor packages. More particularly, example embodiments relate to multi-chip packages including a plurality of stacked chips.

### 2. Description of the Related Art

In a multi-chip package including a plurality of semiconductor chips stacked on a package substrate, chip pads on the semiconductor chips and substrate pads on the package substrate may be electrically connected to each other through a bonding wire. However, the communication speed between the semiconductor chips and the package substrate electrically connected to each other through the bonding wire may be slow.

### SUMMARY

Example embodiments provide semiconductor packages having enhanced electrical characteristics.

According to example embodiments, there is provided a semiconductor package. The semiconductor package may include a package substrate including a first conductive pad at an upper portion thereof, a lower semiconductor chip stack structure including dynamic random access memory (DRAM) chips that are stacked in a vertical direction on the package substrate and electrically connected to each other by a through electrode, an upper semiconductor chip stack structure including flash memory chips, each of the flash memory chips may include a second conductive pad at an upper portion thereof, stacked in the vertical direction on the lower semiconductor chip stack structure, a conductive connection pattern contacting an upper surface of the first conductive pad and extending in the vertical direction, and a bonding wire contacting at least one of the second conductive pads and being electrically connected to the conductive connection pattern.

According to example embodiments, there is provided a semiconductor package. The semiconductor package may include a package substrate including a first conductive pad at an upper portion thereof, a semiconductor chip stack structure including semiconductor chips that are stacked in a vertical direction on the package substrate and electrically connected to each other by a through electrode, a conductive connection pattern including an adhesion portion contacting an upper surface of the first conductive pad and having a shape of a hemisphere and a vertical extension portion contacting an upper surface of the adhesion portion and extending in the vertical direction, a molding member on the package substrate and covering sidewalls of the semiconductor chip stack structure and the conductive connection pattern, and a second conductive pad on the molding member and contacting an upper surface of the conductive connection pattern.

According to example embodiments, there is provided a semiconductor package. The semiconductor package may include a package substrate including a first conductive pad at an upper portion thereof, a lower semiconductor chip stack structure including first semiconductor chips that are stacked in a vertical direction on the package substrate and electrically connected to each other by a through electrode, a conductive connection pattern contacting an upper surface of the first conductive pad and extending in the vertical direction, a first molding member on the package substrate and covering sidewalls of the lower semiconductor chip stack structure and the conductive connection pattern, a second conductive pad on an upper surface of the first molding member and contacting an upper surface of the conductive connection pattern, an upper semiconductor chip stack structure including second semiconductor chips, each of which may include a third conductive pad at an upper portion thereof, stacked in the vertical direction on the first molding member and the lower semiconductor chip stack structure, a bonding wire contacting at least one of the third conductive pads and contacting the second conductive pad, and a second molding member on the first molding member and the lower semiconductor chip stack structure and covering sidewalls of the upper semiconductor chip stack structure, the second conductive pad and the bonding wire.

In semiconductor packages in accordance with example embodiments, the communication speed between the package substrate and the semiconductor chips stacked on the package substrate may be enhanced, and the heat dissipation of the semiconductor package may be enhanced.

### BRIEF DESCRIPTION OF THE DRAWINGS

FIG. 1 is a cross-sectional view illustrating a semiconductor package in accordance with example embodiments.

FIGS. 2 to 9 are cross-sectional views illustrating a method of manufacturing a semiconductor package.

FIG. 10 is a cross-sectional view illustrating a semiconductor package in accordance with example embodiments.

FIG. 11 is a cross-sectional view illustrating a semiconductor package in accordance with example embodiments.

FIG. 12 is a cross-sectional view illustrating a semiconductor package in accordance with example embodiments.

### DETAILED DESCRIPTION OF EXAMPLE EMBODIMENTS

Hereinafter, example embodiments will be explained in detail with reference to the accompanying drawings. It will be understood that, although the terms “first,” “second,” and/or “third” may be used herein to describe various materials, layers, regions, pads, electrodes, patterns, structure and/or processes, these various materials, layers, regions, pads, electrodes, patterns, structure and/or processes should not be limited by these terms. These terms are only used to distinguish one material, layer, region, pad, electrode, pattern, structure or process from another material, layer, region, pad, electrode, pattern, structure or process. Thus, “first”, “second” and/or “third” may be used selectively or interchangeably for each material, layer, region, electrode, pad, pattern, structure or process respectively.

A direction substantially parallel or parallel to an upper surface of a wafer, a substrate or a chip may be referred to as a horizontal direction, and a direction substantially perpendicular or perpendicular to the upper surface of the wafer, the substrate or the chip may be referred to as a vertical direction.

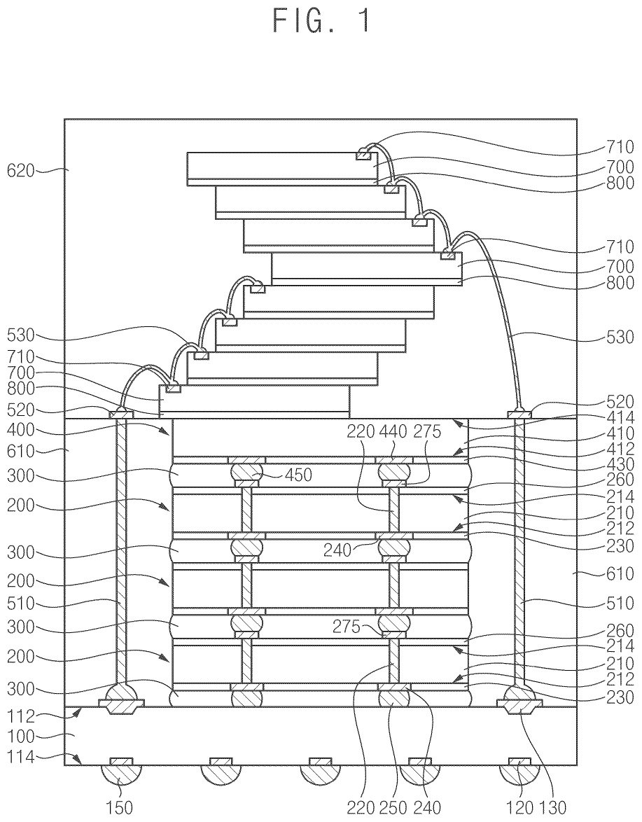

FIG. 1 is a cross-sectional view illustrating a semiconductor package in accordance with example embodiments.

Referring to FIG. 1, the semiconductor package may include a package substrate 100, a semiconductor chip stack structure, a conductive connection structure and a molding structure. The semiconductor package may further include a first conductive connection member 150 and a second conductive pad 130.

The package substrate 100 may include first and second surfaces 112 and 114 opposite to each other in the vertical direction, and for example, may be a printed circuit board (PCB). The PCB may be a multi-layer circuit board having various circuit patterns therein, and a first conductive pad 120, which may be a part of the circuit patterns, and a second conductive pad 130 contacting a part of the circuit patterns and being electrically connected thereto are shown in FIG. 1. The first conductive pad 120 may be disposed adjacent to the second surface 114 of the package substrate 100, and the second conductive pad 130 may be disposed on the first surface 112 of the package substrate 100.

In example embodiments, the second conductive pad 130 may include a lower portion in a groove on the first surface 112 of the package substrate 100 and an upper portion on the lower portion and protruding above the first surface 112 of the package substrate 100. A width of the upper portion of the second conductive pad 130 may be greater than a width of the lower portion thereof. A plurality of first conductive pads 120 may be spaced apart from each other in the horizontal direction, and a plurality of second conductive pads 130 may be spaced apart from each other in the horizontal direction.

Each of the first and second conductive pads 120 and 130 may include a metal or alloy thereof, e.g., nickel, copper, aluminum, gold, etc.

The first conductive connection member 150 may be disposed beneath the second surface 114 of the package substrate 100, and may contact the first conductive pad 120. The first conductive connection member 150 may be electrically connected to a part of the circuit patterns in the package substrate 100 through the first conductive pad 120.

The first conductive connection member 150 may have a shape of, e.g., a bump or a ball. In example embodiments, a plurality of first conductive connection members 150 may be spaced apart from each other in the horizontal direction. The first conductive connection member 150 may include, e.g., a solder that is an alloy of tin, silver, copper, lead, etc.

The semiconductor chip stack structure may include a lower semiconductor chip stack structure and an upper semiconductor chip stack structure that may be stacked in the vertical direction.

The lower semiconductor chip stack structure may include first semiconductor chips 200 and a second semiconductor chip 400 stacked in the vertical direction, and a first adhesion layer 300 between neighboring ones of the first and second semiconductor chips 200 and 400.

The first semiconductor chip 200 may include a first substrate 210 having first and second surfaces 212 and 214 opposite to each other in the vertical direction. The first substrate 210 may include a semiconductor material, e.g., silicon, germanium, silicon-germanium, or a III-V group compound semiconductor, e.g., GaP, GaAs, GaSb, etc. In example embodiments, the first substrate 210 may be a silicon-on-insulator (SOI) substrate or a germanium-on-insulator (GOI) substrate.

A circuit device of a volatile memory device, e.g., a dynamic random access memory (DRAM) device, a static random access memory (SRAM) device, etc., may be disposed beneath (or, for example, within or surrounded by) the first surface 212 of the first substrate 210, and thus the first semiconductor chip 200 may also be referred to as a DRAM chip or an SRAM chip. The circuit device may include circuit patterns, and a first insulating interlayer may be disposed beneath the first surface 212 of the first substrate 210 to cover the circuit patterns.

A second insulating interlayer 230 may be disposed beneath the first insulating interlayer, and may contain a first wiring structure 240 therein. The first wiring structure 240 may include, e.g., wirings, vias, contact plugs, etc., at a plurality of levels, however, the first wiring structure 240 is shown as a single structure in FIG. 1 for the brevity of the drawing.

The first insulating interlayer and the second insulating interlayer 230 may include an oxide, e.g., silicon oxide, an insulating nitride, e.g., silicon nitride, or a low-k dielectric material. The wirings, the vias and the contact plugs may include, e.g., a metal, a metal nitride, a metal silicide, etc.

A second conductive connection member 250 may be disposed beneath the second insulating interlayer 230, and may contact the first wiring structure 240 to be electrically connected thereto. The second conductive connection member 250 may have a shape of, e.g., a bump or a ball. In example embodiments, a plurality of second conductive connection members 250 may be spaced apart from each other in the horizontal direction. The second conductive connection member 250 may include, e.g., solder.

A through electrode 220 may extend through the first substrate 210 in the vertical direction, and may contact a part of the circuit patterns to be electrically connected thereto. In example embodiments, the through electrode 220 may include a protrusion portion that may protrude upwardly in the vertical direction over the second surface 214 of the first substrate 210, and a protective pattern structure 260 may be disposed on the second surface 214 of the first substrate 210 to cover a sidewall of the protrusion portion of the through electrode 220. In example embodiments, a plurality of through electrodes 220 may be spaced apart from each other in the horizontal direction.

In example embodiments, the through electrode 220 may include a conductive pattern extending in the vertical direction, a barrier pattern on a sidewall of the conductive pattern, and an insulation pattern on an outer sidewall of the barrier pattern. The conductive pattern may include a metal, e.g., a copper, aluminum, tungsten, etc., the barrier pattern may include a metal nitride, e.g., titanium nitride, tantalum nitride, tungsten nitride, etc., and the insulation pattern may include an oxide, e.g., silicon oxide.

In example embodiments, the protective pattern structure 260 may include first and second protective patterns stacked in the vertical direction. The first protective pattern may include an oxide, e.g., silicon oxide, and the second protective pattern may include an insulating nitride, e.g., silicon nitride.

A third conductive pad 275 may be disposed on the protective pattern structure 260, and may contact an upper surface of the through electrode 220. A plurality of third conductive pads 275 may be spaced apart from each other in the horizontal direction according to the layout of the through electrodes 220. The third conductive pad 275 may include a metal, e.g., nickel, copper, aluminum, gold, etc.

The second semiconductor chip 400 may include a second substrate 410 having first and second surfaces 412 and 414 opposite to each other in the vertical direction. A circuit device of a volatile memory device, e.g., a DRAM device, an SRAM device, etc., may be disposed beneath the first surface 412 of the second substrate 410, and thus the second semiconductor chip 400 may also be referred to as a DRAM chip or an SRAM chip. The circuit device may include circuit patterns, and a third insulating interlayer may be disposed beneath the first surface 412 of the second substrate 410 to cover the circuit patterns.

A fourth insulating interlayer 430 may be disposed beneath the third insulating interlayer, and may contain a second wiring structure 440 therein. The second wiring structure 440 may include, e.g., wirings, vias, contact plugs, etc., at a plurality of levels, however, the second wiring structure 440 is shown as a single structure in FIG. 1 for the brevity of the drawing.

A third conductive connection member 450 may be disposed beneath the fourth insulating interlayer 430, and may contact the second wiring structure 440 to be electrically connected thereto. The third conductive connection member 450 may have a shape of, e.g., a bump or a ball. In example embodiments, a plurality of third conductive connection members 450 may be spaced apart from each other in the horizontal direction.

The second substrate 410 may include a semiconductor material, e.g., silicon, germanium, silicon-germanium, or a III-V group compound semiconductor, e.g., GaP, GaAs, GaSb, etc. In example embodiments, the second substrate 410 may be a SOI substrate or a GOI substrate. The third insulating interlayer and the fourth insulating interlayer 430 may include an oxide, e.g., silicon oxide, an insulating nitride, e.g., silicon nitride, or a low-k dielectric material. The wirings, the vias and the contact plugs may include, e.g., a metal, a metal nitride, a metal silicide, etc. The third conductive connection member 450 may include, e.g., solder.

In the lower semiconductor chip stack structure, the second conductive connection member 250 in an upper one of the first semiconductor chips 200 disposed at an upper level may contact the third conductive pad 275 in a lower one of the first semiconductor chips 200 disposed at a lower level, and the third conductive connection member 450 in the second semiconductor chip 400 may contact the third conductive pad 275 in an uppermost one of the first semiconductor chips 200.

In some example embodiments, the first adhesion layer 300 may be interposed between the first semiconductor chips 200, and may cover sidewalls of the second conductive connection member 250 and the third conductive pad 275. The first adhesion layer 300 may also be interposed between the first and second semiconductor chips 200 and 400, and may cover sidewalls of the third conductive connection member 450 and the third conductive pad 275. The first adhesion layer 300 may include, e.g., non-conductive film (NCF).

Alternatively, the first adhesion layer 300 may not be interposed between the first semiconductor chips 200 or between the first and second semiconductor chips 200 and 400, and in this case, the sidewalls of the second and third conductive connection members 250 and 450 and the third conductive pad 275 may be covered by a first molding member 610.

In FIG. 1, the lower semiconductor chip stack structure includes three first semiconductor chips 200 and one second semiconductor chip 400, however, the inventive concept may not be limited thereto, and may include more than three first semiconductor chips 200.

In some example embodiments, the second semiconductor chip 400 may not include the DRAM device or the SRAM device, but may be a dummy chip having the second substrate 410 on which no active device is formed, unlike the first semiconductor chip 200.

The upper semiconductor chip stack structure may include third semiconductor chips 700 stacked in the vertical direction and a second adhesion layer 800 interposed between the third semiconductor chips 700.

The third semiconductor chip 700 may include a circuit device of a non-volatile memory device, e.g., a flash memory device, and thus may also be referred to as a flash memory chip. The circuit device may include circuit patterns.

A fifth conductive pad 710 may be disposed at an upper portion of the third semiconductor chip 700. In example embodiments, a plurality of fifth conductive pads 710 may be spaced apart from each other in the horizontal direction, and each of the fifth conductive pads 710 may contact a part of the circuit patterns to be electrically connected thereto.

In example embodiments, the second adhesion layer 800 may be attached to a lower surface of each of the third semiconductor chips 700. The second adhesion layer 800 attached to the lower surface of an upper one of the third semiconductor chips 700 and an upper surface of a lower one of the third semiconductor chips 700 may contact and be bonded with each other. The second adhesion layer 800 attached to a lower surface of a lowermost one of the third semiconductor chips 700 may contact an upper surface of the lower semiconductor chip stack structure, and thus the lower and upper semiconductor chip stack structures may be bonded with each other.

The second adhesion layer 800 may include an adhesive material, e.g., die attach film (DAF).

In some example embodiments, the third semiconductor chips 700 may be disposed in a cascade shape. In some example embodiments, the third semiconductor chips 700 may be disposed in a zigzag shape. In some example embodiments, the third semiconductor chips 700 may be disposed in a mixed shape of a cascade shape and a zigzag shape. That is, the third semiconductor chips 700 may have a number of shapes, in which a portion or edge of individual third semiconductor chips overhang or extend beyond a portion or edge of adjacent individual third semiconductor chips.

The conductive connection structure may include a first conductive connection pattern 510, a fourth conductive pad 520 and a bonding wire 530, and the molding structure may include first and second molding members 610 and 620 stacked in the vertical direction.

The first conductive connection pattern 510 may contact an upper surface of the second conductive pad 130 on the first surface 112 of the package substrate 100. In example embodiments, the first conductive connection pattern 510 may include a vertical extension portion extending in the vertical direction and a bonding portion contacting a lower surface of the vertical extension portion and the upper surface of the second conductive pad 130 and having a shape of, e.g., a hemisphere.

In example embodiments, an upper surface of the first conductive connection pattern 510 may be coplanar or substantially coplanar with the upper surface of the lower semiconductor chip stack structure, that is, an upper surface of the second semiconductor chip 400. In example embodiments, the first conductive connection pattern 510 may be spaced apart from the lower semiconductor chip stack structure in the horizontal direction, and a plurality of first conductive connection patterns 510 may be spaced apart from each other in the horizontal direction.

The first conductive connection pattern 510 may include a metal, e.g., gold, silver, copper, etc.

The first molding member 610 may be disposed on the package substrate 100, and may cover the lower semiconductor chip stack structure, the second conductive pad 130 and the first conductive connection pattern 510. The first molding member 610 may include, e.g., epoxy molding compound (EMC).

The fourth conductive pad 520 may be disposed on the first molding member 610, and may contact an upper surface of the first conductive connection pattern 510. In example embodiments, a planar area of the fourth conductive pad 520 may be greater than a planar area of the upper surface of the first conductive connection pattern 510. The fourth conductive pad 520 may include a metal, e.g., nickel, copper, aluminum, gold, etc.

A plurality of bonding wires 530 may be spaced apart from each other in the horizontal direction. For example, some ones of the boding wires 530 may contact the fifth conductive pads 710 in lower ones of the third semiconductor chips 700 at respective lower levels of the upper semiconductor chip stack structure and the fourth conductive pad 520, and other ones of the boding wires 530 may contact the fifth conductive pads 710 in upper ones of the third semiconductor chips 700 at respective upper levels of the upper semiconductor chip stack structure and the fourth conductive pad 520.

The bonding wire 530 may include a metal, e.g., copper, aluminum, tungsten, nickel, molybdenum, gold, silver, chromium, tin, titanium, etc.

The second molding member 620 may be disposed on the first molding member 610 and the lower semiconductor chip stack structure, and may cover sidewalls of the upper semiconductor chip stack structure, the fourth conductive pad 520 and the bonding wire 530. The second molding member 620 may include, e.g., EMC. In some example embodiments, the first and second molding members 610 and 620 may include substantially the same or the same material so as to be merged with each other such that the first and second molding members 610 and 620 become integral to one another. Alternatively, the first and second molding members 610 and 620 may include different materials from each other so as to be distinguished from each other and may be distinct and separate layers.

In the lower semiconductor chip stack structure of the semiconductor package, the first and second semiconductor chips 200 and 400 may be electrically connected to each other by the through electrode 220, the third conductive pad 275 and the second and third conductive connection members 250 and 450, and may be electrically connected to the package substrate 100 by the second conductive connection member 250. Thus, the communication speed between the package substrate 100 and each of the first and second semiconductor chips 200 and 400 may be fast (for example, uninterrupted, direct, etc.).

In the upper semiconductor chip stack structure of the semiconductor package, each of the third semiconductor chips 700 may be electrically connected to the package substrate 100 by the bonding wire 530, the fourth conductive pad 520, the first conductive connection pattern 510 and the second conductive pad 130. The third semiconductor chips 700 may be stacked, e.g., in a cascade shape or a zigzag shape, and thus heat generated from the upper semiconductor chip stack structure may be effectively discharged.

As a result, the semiconductor package may include the lower semiconductor chip stack structure having a relatively fast communication speed and the upper semiconductor chip stack structure having a relatively high heat dissipation, so that the semiconductor package may have enhanced electrical characteristics.

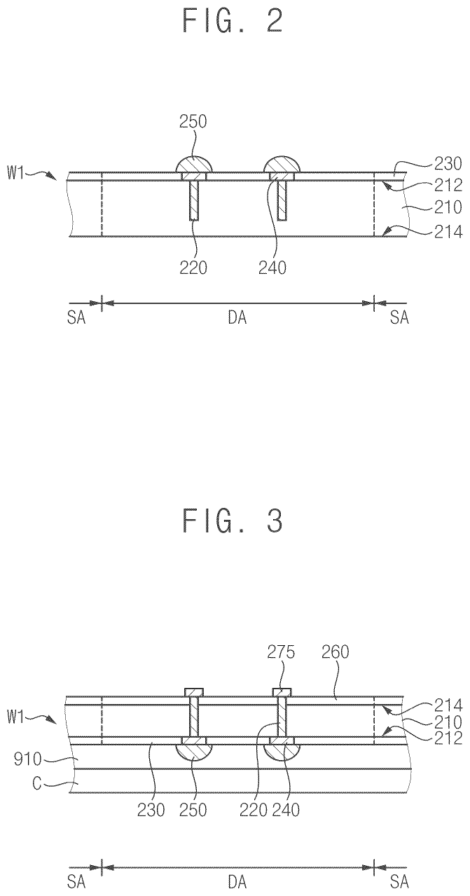

FIGS. 2 to 9 are cross-sectional views illustrating a method of manufacturing a semiconductor package.

Referring to FIG. 2, a first wafer W1 for forming a plurality of first semiconductor chips may be provided.

In example embodiments, the first wafer W1 may include a first substrate 210 having first and second surfaces 212 and 214 opposite to each other in the vertical direction. Additionally, the first wafer W1 may include a plurality of die regions DA and a scribe lane region SA surrounding each of the die regions DA. The first wafer W1 may be cut along the scribe lane region SA by a sawing process to be singulated into the plurality of first semiconductor chips.

In the die region DA, a circuit device may be formed on the first surface 212 of the first substrate 210. The circuit device may include circuit patterns, and a first insulating interlayer may be formed on the first surface 212 of the first substrate 210 to cover the circuit patterns.

A second insulating interlayer 230 may be formed on the first insulating interlayer, and may contain a first wiring structure 240 therein. A second conductive connection member 250 may be formed on the second insulating interlayer 230, and may contact a portion of the first wiring structure 240 to be electrically connected thereto.

A first through electrode 220 extending through a portion of the first substrate 210 adjacent to the first surface 212, that is, an upper portion of the first substrate 210 in the vertical direction and contacting a part of the circuit patterns to be electrically connected thereto may be formed.

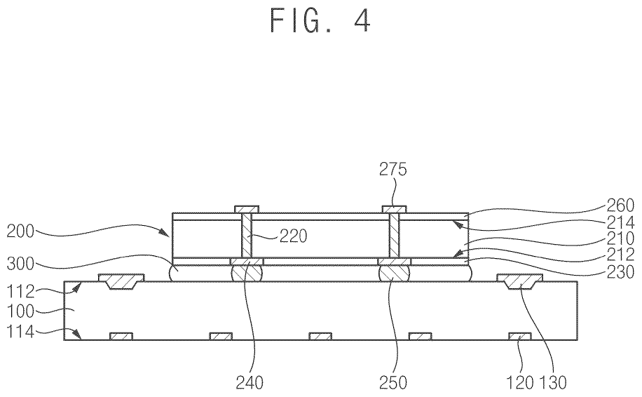

Referring to FIG. 3, a temporary bonding layer 910 may be attached on a carrier substrate C, the carrier substrate C may be bonded with the first wafer W1 such that the temporary bonding layer 910 may contact an upper surface of the second insulating interlayer 230 to cover the second conductive connection member 250, and a structure including the carrier substrate C and the first wafer W1 may be overturned.

The carrier substrate C may include, e.g., a metallic or non-metallic plate, a silicon substrate, a glass substrate, etc. The temporary bonding layer 910 may include a material that may lose adhesion by irradiation of light or heating. In some example embodiments, the temporary bonding layer 910 may include glue or the like.

A portion of the first substrate 210 adjacent to the second surface 214 of the first substrate 210 may be removed by, e.g., a grinding process to expose an upper portion of the through electrode 220, a protective layer structure may be formed on the second surface 214 of the first substrate 210 to cover the through electrode 220, and a planarization process may be performed on the protective layer structure until an upper surface of the through electrode 220 is exposed, so as to form a protective pattern structure 260.

In example embodiments, the planarization process may include a chemical mechanical polishing (CMP) process and/or an etch back process.

A third conductive pad 275 may be formed on the protective pattern structure 260 to contact an upper surface of the through electrode 220.

Referring to FIG. 4, the first wafer W1 may be cut along the scribe lane region SA by, e.g., a sawing process to be singulated into a plurality of first semiconductor chips 200, the temporary bonding layer 910 attached to the carrier substrate C may be divided from the second insulating interlayer 230 and the second conductive connection member 250 so that the carrier substrate C may be divided from each of the first semiconductor chips 200. Each of the divided first semiconductor chips 200 may be bonded with the first surface 112 of the package substrate 100 by, e.g., a thermal compression bonding (TCB) process.

The package substrate 100 may include first and second surfaces 112 and 114 opposite to each other in the vertical direction, and for example, may be a PCB. The PCB may be a multi-layer circuit board having various circuit patterns therein, and a first conductive pad 120, which may be a part of the circuit patterns, and a second conductive pad 130 contacting a part of the circuit patterns to be electrically connected thereto are shown in FIG. 4.

During the TCB process, the second conductive connection member 250 in the first semiconductor chip 200 may contact a part of the circuit patterns in the package substrate 100 to be electrically connected thereto. A first adhesion layer 300 may be interposed between the first semiconductor chip 200 and the package substrate 100, and may surround the second conductive connection member 250.

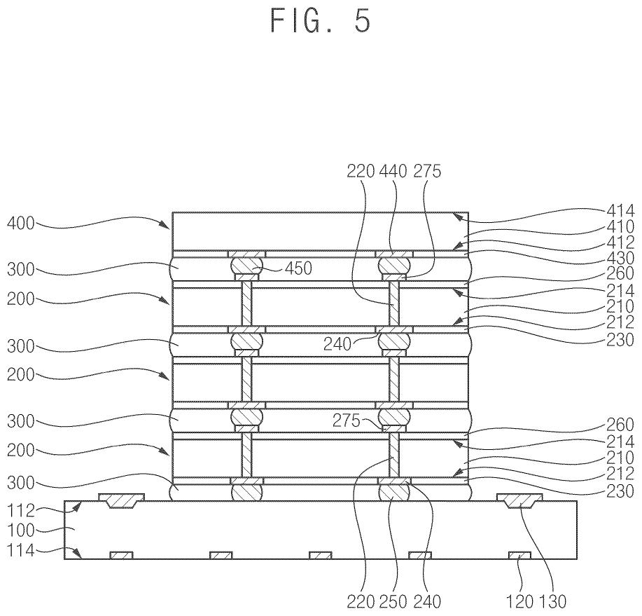

Referring to FIG. 5, additional first semiconductor chips 200 and a second semiconductor chip 400 may be sequentially stacked on the first semiconductor chip 200 bonded with the first surface 112 of the package substrate 100, and a TCB process may be performed so that the additional first semiconductor chips 200 and the second semiconductor chip 400 may be bonded with each other.

The second semiconductor chip 400 may include a second substrate 410 having first and second surfaces 412 and 414 opposite to each other in the vertical direction. A circuit device may be disposed beneath the first surface 412 of the second substrate 410. The circuit device may include circuit patterns, and a third insulating interlayer may be disposed beneath the first surface 412 of the second substrate 410 to cover the circuit patterns.

A fourth insulating interlayer 430 may be disposed beneath the third insulating interlayer, and may contain a second wiring structure 440 therein. A third conductive connection member 450 may be disposed beneath the fourth insulating interlayer 430, and may contact the second wiring structure 440 to be electrically connected thereto.

The second semiconductor chip 400 may be formed by forming the third insulating interlayer, the fourth insulating interlayer 430 and the third conductive connection member 450 on a second wafer, and cutting the second wafer along the scribe lane region by, e.g., a sawing process.

During the TCB process, the second conductive connection member 250 in an upper one of the first semiconductor chips 200 at an upper level may contact the third conductive pad 275 in a lower one of the first semiconductor chips 200 at a lower level, and the third conductive connection member 450 in the second semiconductor chip 400 may contact the third conductive pad 275 in an uppermost one of the first semiconductor chips 200.

A first adhesion layer 300 may be interposed between the first semiconductor chips 200, and may cover sidewalls of the second conductive connection member 250 and the third conductive pad 275. The first adhesion layer 300 may also be interposed between the first and second semiconductor chips 200 and 400, and may cover sidewalls of the third conductive connection member 450 and the third conductive pad 275.

The first semiconductor chips 200, the second semiconductor chip 400, and the first adhesion layers 300 therebetween may form a lower semiconductor chip stack structure.

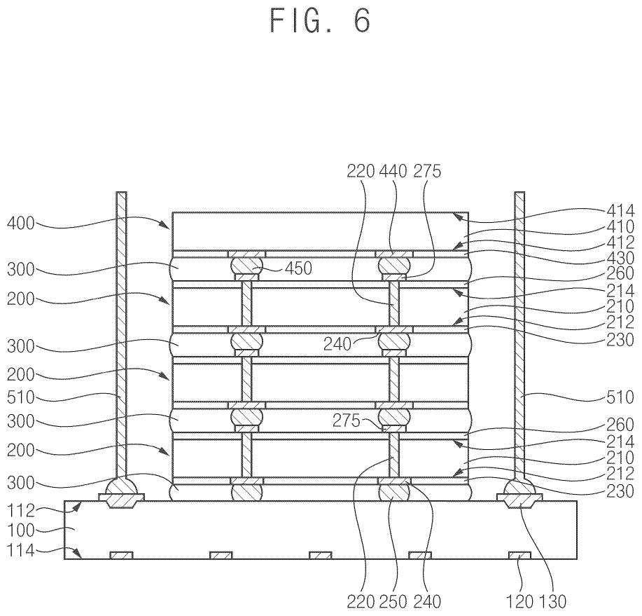

Referring to FIG. 6, for example, a dispensing process may be performed to form a first conductive connection pattern 510 contacting an upper surface of the second conductive pad 130 on the first surface 112 of the package substrate 100.

In example embodiments, the first conductive connection pattern 510 may include a vertical extension portion extending in the vertical direction and a bonding portion contacting a lower surface of the vertical extension portion and the upper surface of the second conductive pad 130 and having a shape of, e.g., a hemisphere.

In example embodiments, an upper surface of the first conductive connection pattern 510 may be coplanar or substantially coplanar with or higher than an upper surface of the lower semiconductor chip stack structure, that is, an upper surface of the second semiconductor chip 400. In some example embodiments, the first conductive connection pattern 510 may be cut, etched, etc. to be coplanar or substantially coplanar with or higher than an upper surface of the lower semiconductor chip stack structure.

In example embodiments, the first conductive connection pattern 510 may be spaced apart from the lower semiconductor chip stack structure in the horizontal direction, and a plurality of first conductive connection patterns 510 may be spaced apart from each other in the horizontal direction.

After the lower semiconductor chip stack structure is formed on the package substrate 100, and the first conductive connection pattern 510 may be formed, however, the inventive concept may not be limited thereto. Thus, in some example embodiments, after forming the first conductive connection pattern 510 on the package substrate 100, and the lower semiconductor chip stack structure may be formed.

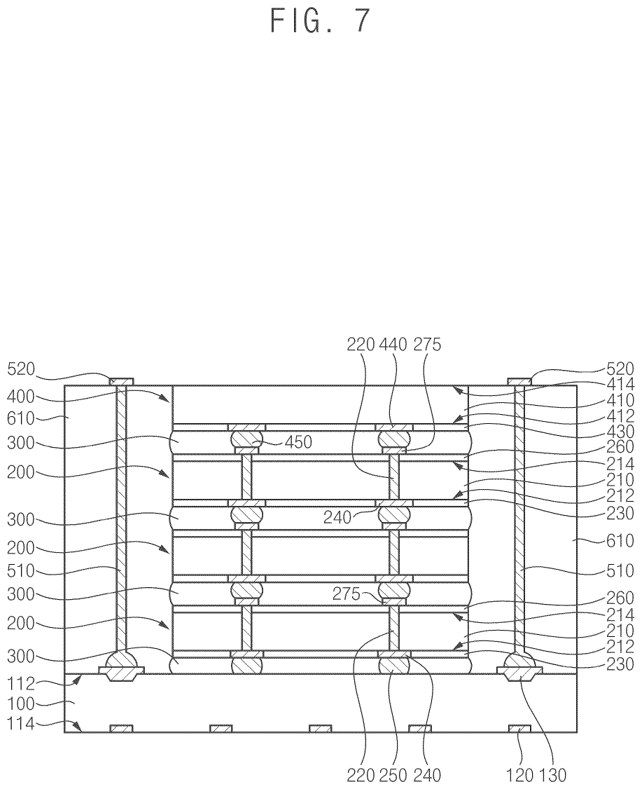

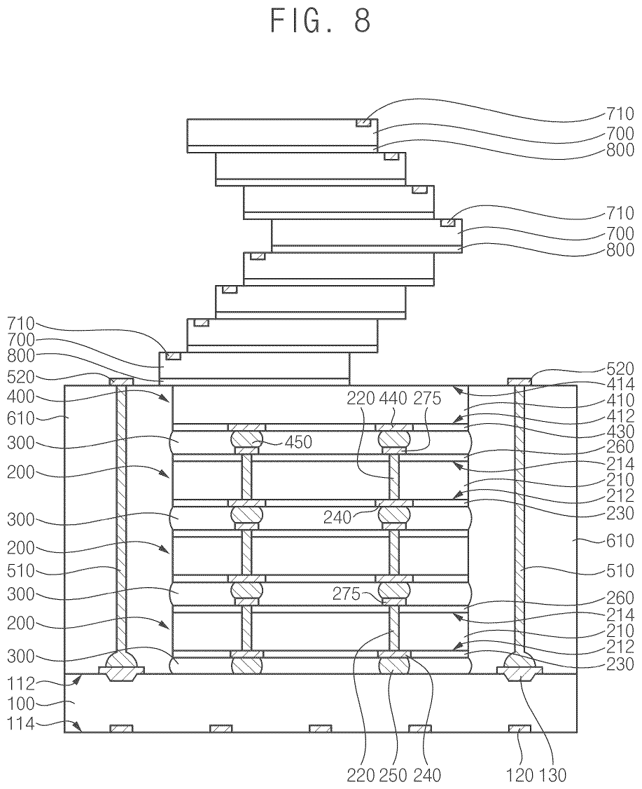

Referring to FIG. 7, a first molding member 610 may be formed on the package substrate 100 to cover the lower semiconductor chip stack structure, and a planarization process may be performed on the first molding member 610 until the upper surface of the lower semiconductor chip stack structure is exposed so that an upper surface of the first molding member 610 may be coplanar or substantially coplanar with the upper surface of the lower semiconductor chip stack structure.

The planarization process may include, e.g., a chemical mechanical polishing (CMP) process and/or an etch back process.

A fourth conductive pad 520 may be formed on the first molding member 610 to contact an upper surface of the first conductive connection pattern 510. In example embodiments, a plurality of fourth conductive pads 520 may be formed to be spaced apart from each other in the horizontal direction.

Referring to FIG. 8, an upper semiconductor chip stack structure may be formed on the lower semiconductor chip stack structure and the first molding member 610.

The upper semiconductor chip stack structure may include third semiconductor chips 700 stacked in the vertical direction and a second adhesion layer 800 interposed between the third semiconductor chips 700. In some example embodiments, the third semiconductor chips 700 may be disposed in a cascade shape. In some example embodiments, the third semiconductor chips 700 may be disposed in a zigzag shape. In some example embodiments, the third semiconductor chips 700 may be disposed in a mixed shape of a cascade shape and a zigzag shape.

In example embodiments, each of the third semiconductor chips may include a fifth conductive pad 710 at an upper portion thereof. A plurality of fifth conductive pads 710 may be spaced apart from each other in the horizontal direction.

The third semiconductor chip 700 may include a circuit device. The circuit device my include circuit patterns, and the fifth conductive pad 710 may contact a part of the circuit patterns to be electrically connected thereto.

In example embodiments, the second adhesion layer 800 may be attached to a lower surface of each of the third semiconductor chips 700, and the second adhesion layer 800 attached to a lower surface of an upper one of the third semiconductor chips 700 at an upper level and an upper surface of a lower one of the third semiconductor chips 700 at a lower level may contact and be bonded with each other. The second adhesion layer 800 attached to a lower surface of a lowermost one of the third semiconductor chips 700 may contact an upper surface of the lower semiconductor chip stack structure, so that the lower and upper semiconductor chip stack structures may be bonded with each other.

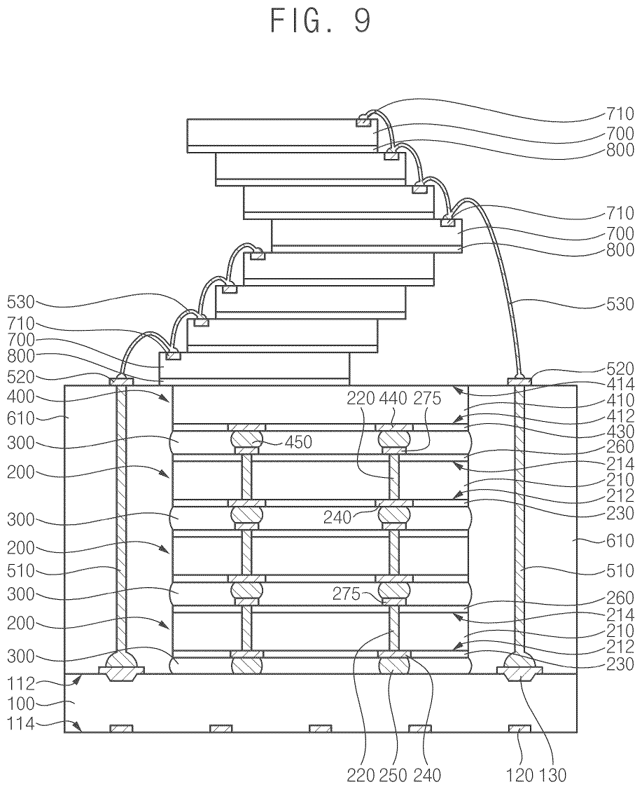

Referring to FIG. 9, a wire bonding process may be performed to form a bonding wire 530 that may contact the fourth and fifth conductive pads 520 and 710 and electrically connect the fourth and fifth conductive pads 520 and 710 with each other.

In example embodiments, a plurality of bonding wires 530 may be spaced apart from each other in the horizontal direction. For example, some ones of the bonding wires 530 may contact the fifth conductive pads 710 in lower ones of the third semiconductor chips 700 at respective lower levels in the upper semiconductor chip stack structure and the fourth conductive pad 520, and other ones of the bonding wires 530 may contact the fifth conductive pads 710 in upper ones of the third semiconductor chips 700 at respective upper levels in the upper semiconductor chip stack structure and the fourth conductive pad 520.

Referring to FIG. 1 again, a second molding member 620 may be formed on the lower semiconductor chip stack structure and the first molding member 610 to cover the lower semiconductor chip stack structure, the fourth conductive pad 520 and the bonding wire 530, and a first conductive connection member 150 may be formed beneath the second surface 114 of the package substrate 100 to complete the manufacturing of the semiconductor package.

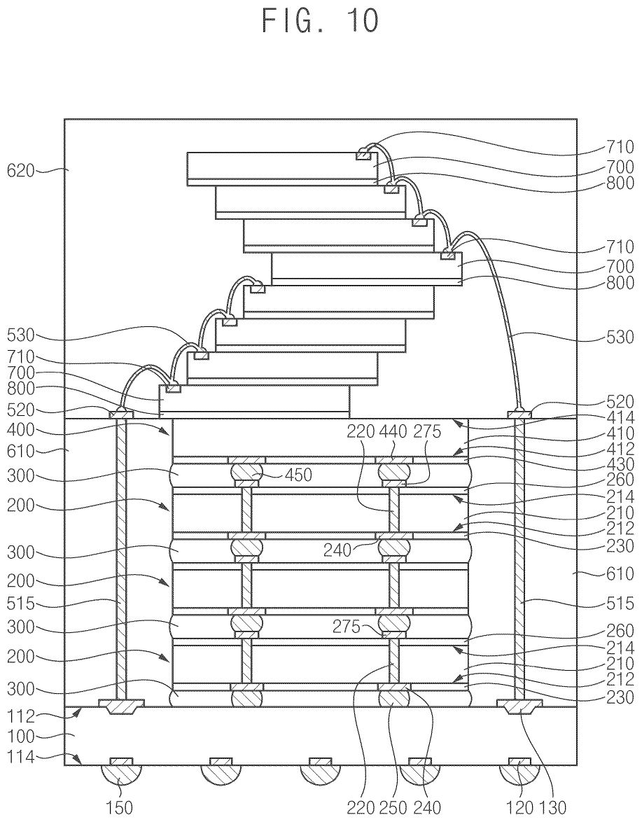

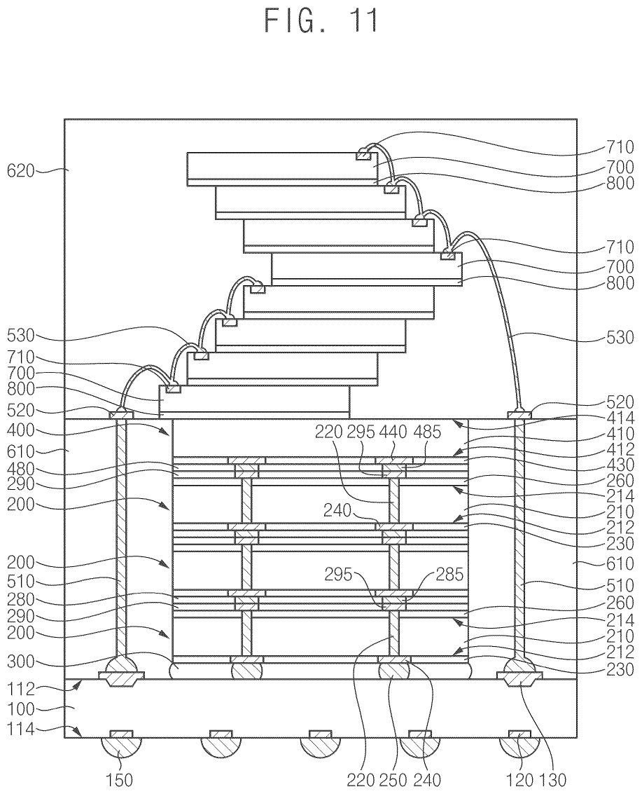

FIG. 10 is a cross-sectional view illustrating a semiconductor package in accordance with example embodiments.

This semiconductor package may be substantially the same or the same as or similar to that of FIG. 1, except for including a second conductive connection pattern 515 instead of the first conductive connection pattern 510, and thus repeated explanations are omitted herein.

Referring to FIG. 10, the second conductive connection pattern 515 may include only the vertical extension portion extending in the vertical direction, and may not include the bonding portion having the shape of the hemisphere.

The semiconductor package including the second conductive connection pattern 515 may be manufactured by following processes.

Particularly, a photoresist layer may be formed on the first surface 112 of the package substrate 100, the photoresist may be patterned to form a photoresist pattern having an opening exposing an upper surface of the second conductive pad 130 on the first surface 112 of the package substrate 100, forming a conductive connection layer including a metal, e.g., copper, aluminum, etc., in the opening by, e.g., an electroplating process or an electroless plating process, and performing a planarization process on the conductive connection layer until an upper surface of the photoresist pattern is exposed to form the second conductive connection pattern 515.

The photoresist pattern may be removed by, e.g., an ashing process and/or a stripping process.

Processes substantially the same as or similar to those illustrated with respect to FIGS. 4 and 5 may be performed to form the lower semiconductor chip stack structure on the package substrate 100, processes substantially the same as or similar to those illustrated with respect to FIG. 7 may be performed so that the first molding member 610 may be formed on the package substrate 100 to cover sidewalls of the lower semiconductor chip stack structure and the second conductive connection pattern 515 and that the fourth conductive pad 520 may be formed to contact an upper surface of the second conductive connection pattern 515.

Processes substantially the same as or similar to those illustrated with respect to FIGS. 8 and 9 and FIG. 1 may be performed to complete the manufacturing the semiconductor package.

FIG. 11 is a cross-sectional view illustrating a semiconductor package in accordance with example embodiments.

This semiconductor package may be substantially the same as or similar to that of FIG. 1, except for the type of stack of the lower semiconductor chip stack structure, and thus repeated explanations are omitted herein.

Referring to FIG. 11, the first semiconductor chips 200 included in the lower semiconductor chip stack structure may be bonded with each other not by a TCB process but by a hybrid copper bonding (HCB) process.

Thus, each of the first semiconductor chips 200 may include a second bonding layer 290 containing a second bonding pattern 295 on the through electrode 220 and the protective pattern structure 260, and the second bonding pattern 295 may contact an upper surface of the through electrode 220. Additionally, each of other ones of the first semiconductor chips 200 except for a lowermost one of the first semiconductor chips 200 may include a first bonding layer 280 containing a first bonding pattern 285 beneath the second insulating interlayer 230, and the first bonding pattern 285 may contact the first wiring structure 240 to be electrically connected thereto.

In example embodiments, the first bonding layer 280 of an upper one of the first semiconductor chips 200 at an upper level and the second bonding layer 290 of a lower one of the first semiconductor chips 200 at a lower level may contact each other to form a first bonding layer structure, and the first and second bonding patterns 285 and 295 may be bonded with each other to form a first bonding pattern structure.

The second semiconductor chip 400 may include a third bonding layer 480 containing a third bonding pattern 485 beneath the fourth insulating interlayer 430, and the third bonding pattern 485 may contact the second wiring structure 440 to be electrically connected thereto.

In example embodiments, the third bonding layer 480 of the second semiconductor chip 400 and the second bonding layer 290 of an uppermost one of the first semiconductor chips 200 may contact each other to form a second bonding layer structure, and the second and third bonding patterns 295 and 485 may be bonded with each other to form a second bonding pattern structure.

In example embodiments, each of the first to third bonding layers 280, 290 and 480 may include an insulating material, e.g., silicon carbonitride, silicon oxide, etc., and each of the first to third bonding patterns 285, 295 and 485 may include a metal, e.g., copper.

FIG. 11 shows that the lowermost one of the first semiconductor chips 200 and the package substrate 100 are bonded not by an HCB process but by a TCB process, however, the inventive concept may not be limited thereto, and may also be bonded with each other by an HCB process.

In this case, the first bonding layer 280 containing the first bonding pattern 285 may be disposed beneath the second insulating interlayer 230 of the lowermost one of the first semiconductor chips 200, and a fourth bonding layer containing a fourth bonding pattern may be disposed on the first surface 112 of the package substrate 100. Thus, the first bonding layer 280 and the fourth bonding layer may be bonded with each other to form a third bonding layer structure, and the first bonding pattern 285 and the fourth bonding pattern may be bonded with each other to form a third bonding pattern structure.

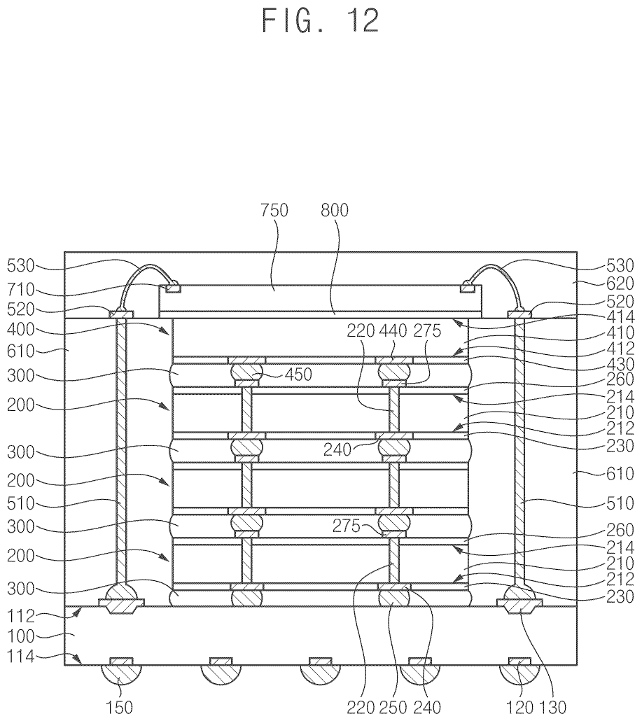

FIG. 12 is a cross-sectional view illustrating a semiconductor package in accordance with example embodiments.

This semiconductor package may be substantially the same as or similar to that of FIG. 1, except for including a fourth semiconductor chip 750 instead of the third semiconductor chips 700, and thus repeated explanations are omitted herein.

Referring to FIG. 12, unlike the semiconductor package of FIG. 1, the semiconductor package may include the fourth semiconductor chip 750 instead of the upper semiconductor chip stack structure including the third semiconductor chips 700.

That is, the semiconductor chip stack structure included in the semiconductor package may include the lower semiconductor chip stack structure and the fourth semiconductor chip 750 bonded with the lower semiconductor chip stack structure by the second adhesion layer 800.

The fourth semiconductor chip 750 may be electrically connected to the circuit patterns of the package substrate 100 by the fifth conductive pad 710, the bonding wire 530, the fourth conductive pad 520, the first conductive connection pattern 510 and the second conductive pad 130.

In example embodiments, the fourth semiconductor chip 750 may include a circuit device, e.g., a logic device, and thus may also be referred to as a logic chip. The circuit device may include circuit patterns, and the fifth conductive pad 710 may contact a part of the circuit patterns to be electrically connected thereto.

When the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present invention. Accordingly, all such modifications are intended to be included within the scope of example embodiments as defined in the claims.

What is claimed is:

1. A semiconductor package comprising:
a package substrate including a first conductive pad at an upper portion thereof;
a lower semiconductor chip stack structure including dynamic random access memory (DRAM) chips stacked in a vertical direction on the package substrate, the DRAM chips being electrically connected to each other by a through electrode;
an upper semiconductor chip stack structure including flash memory chips stacked in the vertical direction on the lower semiconductor chip stack structure, each of the flash memory chips including a second conductive pad at an upper portion thereof;
a conductive connection pattern contacting an upper surface of the first conductive pad and extending in the vertical direction; and
a bonding wire contacting at least one of the second conductive pads, the bonding wire being electrically connected to the conductive connection pattern.

2. The semiconductor package according to claim 1, wherein the conductive connection pattern includes:
a vertical extension portion extending in the vertical direction; and
a bonding portion contacting a lower surface of the vertical extension portion and the upper surface of the first conductive pad.

3. The semiconductor package according to claim 2, wherein the bonding portion of the conductive connection pattern has a shape of a hemisphere.

4. The semiconductor package according to claim 1, wherein the conductive connection pattern includes gold or copper.

5. The semiconductor package according to claim 1, further comprising a third conductive pad on an upper surface of the conductive connection pattern,
wherein the bonding wire contacts an upper surface of the third conductive pad.

6. The semiconductor package according to claim 5, wherein a planar area of the third conductive pad is greater than a planar area of the conductive connection pattern.

7. The semiconductor package according to claim 1, wherein
each of the DRAM chips includes:
a substrate having first and second surfaces opposite to each other in the vertical direction;
a through electrode extending through the substrate in the vertical direction;
a third conductive pad on the second surface of the substrate, the third conductive pad contacting an upper surface of the through electrode;
a wiring structure beneath the first surface of the substrate, the wiring structure being electrically connected to the through electrode; and
a conductive connection member contacting the wiring structure, and
the conductive connection member of an upper one of the DRAM chips at an upper level contacts the third conductive pad of a lower one of the DRAM chips at a lower level.

8. The semiconductor package according to claim 7, further comprising an adhesion layer between the DRAM chips, the adhesion layer covering sidewalls of the conductive connection member and the third conductive pad.

9. The semiconductor package according to claim 1, wherein
each of the DRAM chips includes:
a substrate having first and second surfaces opposite to each other in the vertical direction;
a through electrode extending through the substrate in the vertical direction;
an insulating interlayer beneath the first surface of the substrate, the insulating interlayer containing a wiring structure electrically connected to the through electrode;
a protective pattern structure on the second surface of the substrate, the protective pattern structure covering a portion of a sidewall of the through electrode;
a first bonding layer beneath the insulating interlayer, the first bonding layer containing a first bonding pattern electrically connected to the wiring structure; and
a second bonding layer on the protective pattern structure, the second bonding layer containing a second bonding pattern electrically connected to the through electrode, and
the first bonding layer and the first bonding pattern of an upper one of the DRAM chips at an upper level contacts the second bonding layer and the second bonding pattern, respectively, of a lower one of the DRAM chips at a lower level.

10. The semiconductor package according to claim 9, wherein each of the first and second bonding layers includes silicon carbonitride, and each of the first and second bonding patterns includes copper.

11. The semiconductor package according to claim 1, wherein the upper semiconductor chip stack structure includes an adhesion layer between the flash memory chips.

12. The semiconductor package according to claim 1, wherein the flash memory chips are in a cascade shape or a zigzag shape in the vertical direction.

13. A semiconductor package comprising:
a package substrate including a first conductive pad at an upper portion thereof;
a semiconductor chip stack structure including semiconductor chips stacked in a vertical direction on the package substrate, the semiconductor chips being electrically connected to each other by a through electrode;
a conductive connection pattern including
an adhesion portion contacting an upper surface of the first conductive pad and having a shape of a hemisphere; and
a vertical extension portion contacting an upper surface of the adhesion portion and extending in the vertical direction;
a molding member on the package substrate, the molding member covering sidewalls of the semiconductor chip stack structure and the conductive connection pattern; and
a second conductive pad on the molding member, the second conductive pad contacting an upper surface of the conductive connection pattern.

14. The semiconductor package according to claim 13, wherein a planar area of the second conductive pad is greater than a planar area of the conductive connection pattern.

15. The semiconductor package according to claim 13, wherein an upper surface of the molding member is coplanar with an upper surface of the semiconductor chip stack structure.

16. The semiconductor package according to claim 13, wherein the conductive connection pattern includes gold, and the second conductive pad includes nickel, copper, aluminum, or gold.

17. A semiconductor package comprising:
a package substrate including a first conductive pad at an upper portion thereof;
a lower semiconductor chip stack structure including first semiconductor chips stacked in a vertical direction on the package substrate, the first semiconductor chips being electrically connected to each other by a through electrode;
a conductive connection pattern contacting an upper surface of the first conductive pad and extending in the vertical direction;
a first molding member on the package substrate, the first molding member covering sidewalls of the lower semiconductor chip stack structure and the conductive connection pattern;
a second conductive pad on an upper surface of the first molding member, the second conductive pad contacting an upper surface of the conductive connection pattern;
an upper semiconductor chip stack structure including second semiconductor chips stacked in the vertical direction on the first molding member and the lower semiconductor chip stack structure, each of the second semiconductor chips including a third conductive pad at an upper portion thereof;
a bonding wire contacting at least one of the third conductive pads, the bonding wire contacting the second conductive pad; and
a second molding member on the first molding member and the lower semiconductor chip stack structure, the second molding member covering sidewalls of the upper semiconductor chip stack structure, the second conductive pad and the bonding wire.

18. The semiconductor package according to claim 17, wherein the conductive connection pattern includes:
a vertical extension portion extending in the vertical direction; and
a bonding portion contacting a lower surface of the vertical extension portion and the upper surface of the first conductive pad.

19. The semiconductor package according to claim 17, wherein a planar area of the second conductive pad is greater than a planar area of the conductive connection pattern.

20. The semiconductor package according to claim 17, wherein
each of the first semiconductor chips includes:
a substrate having first and second surfaces opposite to each other in the vertical direction;
a through electrode extending through the substrate in the vertical direction;
a fourth conductive pad on the second surface of the substrate, the fourth conductive pad contacting an upper surface of the through electrode;
a wiring structure beneath the first surface of the substrate, the wiring structure being electrically connected to the through electrode; and
a conductive connection member contacting the wiring structure, and
the conductive connection member of an upper one of the first semiconductor chips at an upper level contacts the third conductive pad of a lower one of the first semiconductor chips at a lower level.
